(19) United States
(12) Patent Application Publication
(10) Pub. No.: US 2014/0027162 A1
(43) Pub. Date: Jan. 30, 2014

(54) PRINTED CIRCUIT BOARD AND METHOD FOR MANUFACTURING A PRINTED CIRCUIT BOARD

(71) Applicant: WISTRON CORPORATION, New Taipei City (TW)

(72) Inventors: LUNG-MING CHAN, New Taipei City (TW); HUI-LIN LU, New Taipei City (TW); SHU-TING HSU, New Taipei City (TW); JUI-YUN FAN, New Taipei City (TW); HUI-YING CHOU, New Taipei City (TW)

(73) Assignee: WISTRON CORPORATION, New Taipei City (TW)

(21) Appl. No.: 13/684,298

(22) Filed: Nov. 23, 2012

(30) Foreign Application Priority Data
Jul. 25, 2012 (TW) 101126831

(51) Int. Cl. H05K 3/00; H05K 1/09

(52) U.S. Cl. CPC H05K 3/0073; H05K 1/092
USPC 174/257; 228/165

(57) ABSTRACT

A printed circuit board is disclosed. The printed circuit board includes a solder mask area and at least one chip attachment area. The at least one chip attachment area has an isolation solder mask layer such that the chip attachment area forms a plurality of chip sub-attachment areas to reduce an area of a solder paste smeared on the chip attachment area, and the isolation solder mask layer has at least one hole.

### BACKGROUND OF THE INVENTION

1. Field of the Invention

The present invention relates to the improvement of the solder pad used in the printed circuit board.

2. Description of the Related Art

Surface Mount Technology (SMT) is a manufacturing method for soldering electronic components to printed circuit boards. In this welding method, a solder paste is smeared on the pad of the printed circuit board, then a mounting apparatus is used to place components (such as IC chips or transistors) on the pad with the solder paste, and finally the solder paste is melted by the reflow of hot air to combine the components with the printed circuit board.

Due to the demand for high speed, thinness and lightness for current electronic products, the removal of heat from components has become a major issue. For example, in order to have a good cooling effect for the chips of Quad Flat No leads (QFN), the thermal pad area is relatively large, and the corresponding solder pad area is relatively large as well.

FIG. 1 illustrates the printed circuit board 1a of the prior art. The surface of the copper foil substrate 10a of the printed circuit board has a solder mask area 112a, a chip attachment area 114a, and a pin area 116a. Usually, the solder paste is smeared on the chip attachment area 114a and on the pin area 116a (both collectively referred to as the solder pad). However, because the solder paste melts into a liquid during the process of hot air reflow, there is a size limitation. When the smearing area of the solder paste is too large, the components on the area will move such that the components cannot be accurately located in the chip attachment area 114a and the distribution of the solder paste will be uneven.

### SUMMARY OF THE INVENTION

It is an object of the present invention to provide a printed circuit board that can prevent undesired movement of the chips when the solder paste is smeared on a large area of the chip sub-attachment area of the surface of the substrate.

It is another object of the present invention to provide a method for manufacturing a printed circuit board.

To achieve the abovementioned objects, the printed circuit board of the invention is used to set at least one chip. The printed circuit board includes a copper foil substrate with a surface of the substrate and at least one hole. The surface of the substrate includes a solder mask area and at least one chip attachment area. The solder mask area has a main solder mask layer. The at least one chip attachment area has an isolation solder mask layer used to divide the at least one chip attachment area into a plurality of chip sub-attachment areas; each chip sub-attachment area has a sub-attachment area solder paste layer; each solder paste layer is used to connect to the at least one chip. The at least one hole is located in the isolation solder mask layer.

The method for manufacturing a printed circuit board of the invention includes the following steps: Setting at least one hole in the copper foil substrate; Adding a main solder mask layer and an isolation solder mask layer on a surface of the substrate of the copper foil substrate to form a plurality of chip sub-attachment areas; Smearing the sub-attachment area solder paste layer on each chip sub-attachment area.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 shows the printed circuit board of the prior art.

FIG. 2 is a top view of the printed circuit board of the first embodiment of the invention.

FIG. 3 is a side-sectional view of the A-A direction of the printed circuit board shown in FIG. 2.

FIG. 4 is the top view of the printed circuit board of a second embodiment of the invention.

FIG. 5 is the step flow chart of the method for manufacturing a printed circuit board of the invention.

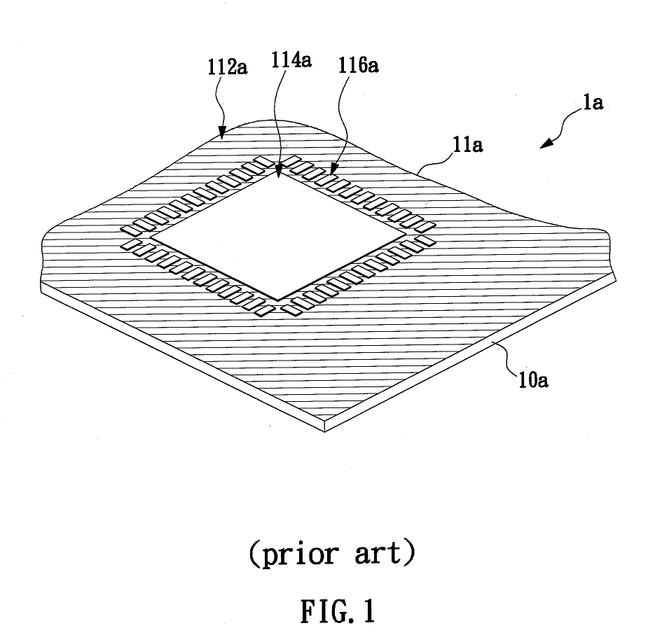

### DETAILED DESCRIPTION OF THE PREFERRED EMBODIMENT

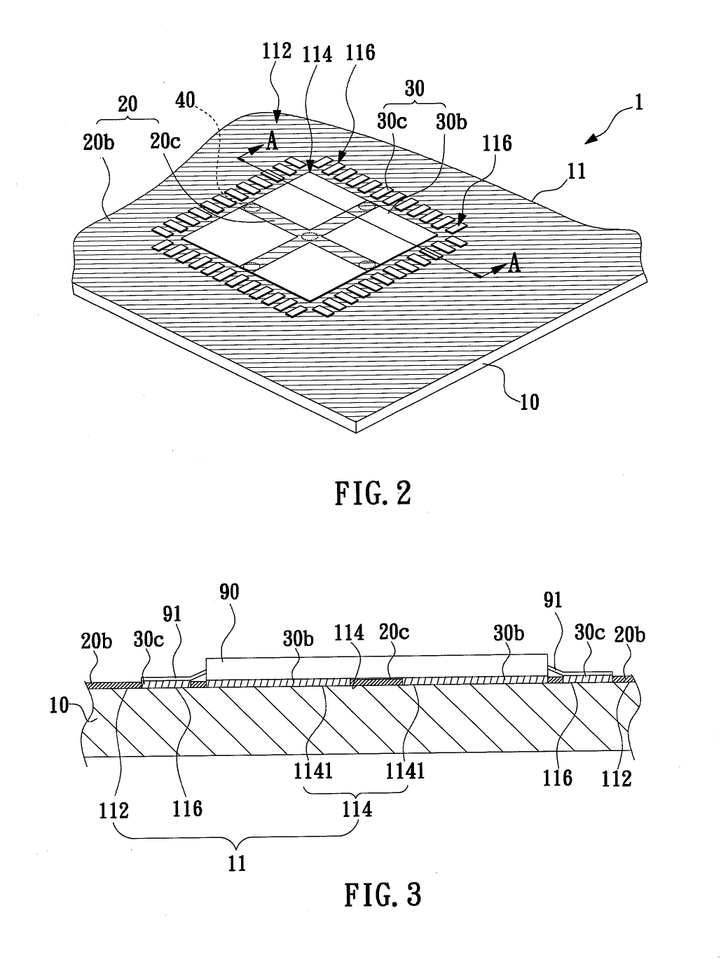

Hereinafter refer to FIG. 2 and FIG. 3, which present schematic diagrams of the structure of the printed circuit board of the first embodiment of the present invention.

As shown in FIG. 2, in the first embodiment of the invention, a printed circuit board 1 includes a copper foil substrate 10, a solder mask layer 20, a solder paste layer 30, and at least one hole 40. The solder mask layer 20 includes a main solder mask layer 20b and an isolation solder mask layer 20c, and the solder paste layer 30 includes a sub-attachment area solder paste layer 30b and a pin area solder paste layer 30c.

As shown in FIG. 2 and FIG. 3, in an embodiment of the invention, the copper foil substrate 10 includes a surface of the substrate 11 that includes a solder mask area 112, at least one chip attachment area 114, and a plurality of pin areas 116 within the chip attachment area 114. The plurality of pin areas 116 are disposed around the chip attachment area 114.

The solder mask area 112 is equipped with a main solder mask layer 20b.

The chip attachment area 114 is equipped with an isolation solder mask layer 20c used to divide the chip attachment area 114 into a plurality of chip sub-attachment areas 1141. Each chip sub-attachment area 1141 is equipped with a sub-attachment area solder paste layer 30b used to connect to the chip 90 so that the chip 90 can be fixed on the surface of the substrate 11. In the first embodiment of the invention, when the isolation solder mask layer 20c is set on the chip attachment area 114, the shape of its top view is a cross, such that the chip attachment area 114 is divided into four chip sub-attachment areas 1141.

The number of the plurality of pin areas 116 corresponds to the number of the pins 91 of the chip 90, and each pin area 116 is equipped with a pin area solder paste layer 30c used to connect to the pins 91 of the chip 90 so that the chip 90 can be fixed on the surface of the substrate 11.

The at least one hole 40 is located in the isolation solder mask layer 20c and is used to cool the chip 90 set on the chip attachment area 114. In the first embodiment of the invention, the number of the holes 40 is five, and the distance between each hole 40 and another one is substantially equal, so as to allow the chip 90 to dissipate heat energy equally, but the number and spacing of the holes 40 are not limited to the above description.

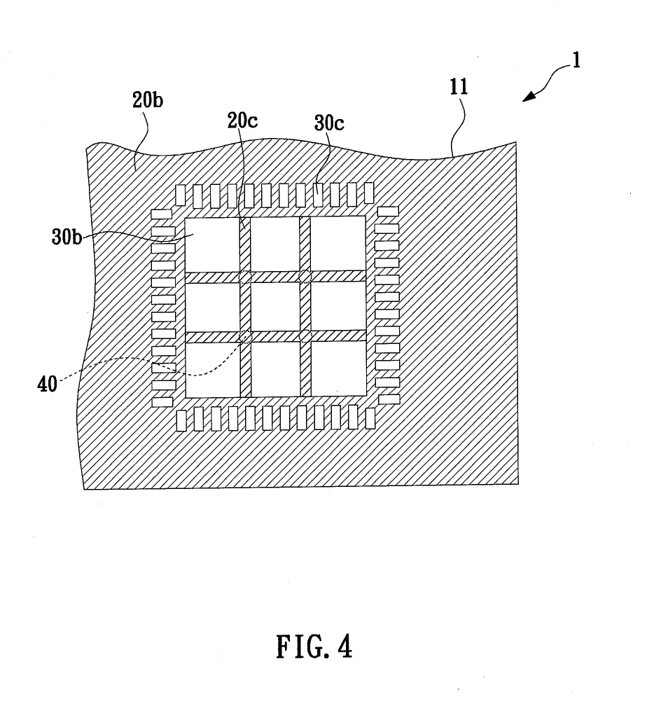

Please continue to refer to FIG. 4, which presents the top view of the printed circuit board in the second embodiment of the invention.

As shown in FIG. 2, when the area of the chip attachment area 114 is large, then in order to keep the area of the sub-attachment area solder paste layer 30b from being correspondingly large, in the second embodiment of the invention, the top view shape of the isolation solder mask layer 20c is designed in a tick-tack-toe grid so as to divide the chip attachment area 114 into nine smaller chip sub-attachment areas 1141.

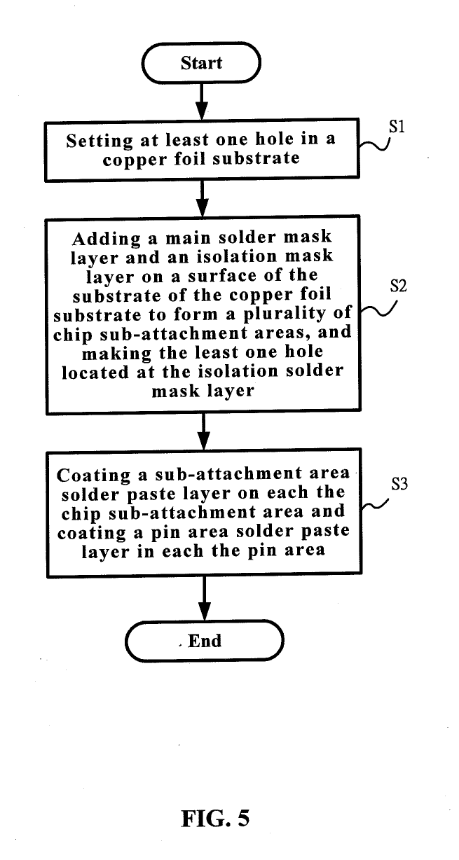

Finally, please continue to refer to FIG. 2, FIG. 3, and FIG. 5. FIG. 5 is the step flow chart of the method for manufacturing a printed circuit board of the invention.

step S1: setting at least one hole 40 in the copper foil substrate 10.

First, at least one hole 40 is set in the copper foil substrate 10.

step S2: adding a main solder mask layer 20b and an isolation solder mask layer 20c on a surface of the substrate 11 of the copper foil substrate 10 to form a plurality of chip sub-attachment areas 1141 and a plurality of pin areas 116, and making at least one hole 40 located at the isolation solder mask layer 20c.

Then reserving a plurality of chip sub-attachment areas 1141 and pin areas 116 on the surface of the substrate 11 of the copper foil substrate 10 by using a fixture and adding the solder mask layer 20 (including the main solder mask layer 20b and the isolation solder mask layer 20c) on the unreserved areas of the surface of the substrate 11. After the solder mask layer 20 is added, the plurality of chip sub-attachment areas 1141 and the plurality of pin areas 116 are formed on the surface of the substrate 11, and the at least one hole 40, which is set in advance, is located at the isolation solder mask layer 20c so as to increase the cooling effect of the chip 90 through the hole 40 when the chip 90 is set in the chip attachment area 114.

step S3: coating the sub-attachment area solder paste layer 30b on each chip sub-attachment area 1141 and coating the pin area solder paste layer 30c on each pin area 116, 116a.

After step S2 is completed, coating the solder paste layer 30 (including the sub-attachment area solder paste layer 30b and the pin area solder paste layer 30c) on the areas of the surface of the substrate 11 that are not coated by the solder mask layer 20, which are the plurality of chip sub-attachment areas 1141 and the plurality of pin areas 116.

It must be noted that the method for manufacturing a printed circuit board of the invention is not limited by the above-mentioned step sequence, which can be changed as long as the purpose of this invention is reached.

In this invention, because the chip attachment area 114, originally large in area, forms a plurality of chip sub-attachment areas 1141 of smaller area by the isolation of the isolation solder mask layer 20c set on the chip attachment area 114, the area of the solder paste layer 30b which is originally coated on the chip attachment area 114 is reduced. The smaller area of the coated solder paste effectively reduces the problems of the prior art.

In summary, regardless of purposes, means and effectiveness, this invention has characteristics that are quite different from those of known technology, and we earnestly request that the examiners approve the patent to benefit society. However, it is noted that many of the above-mentioned embodiments are only for illustrative purposes; the claims of this invention should depend on the claims rather than being limited to the embodiments.

What is claimed is:

1. A printed circuit board used for setting at least one chip, the printed circuit board comprising a copper foil substrate and at least one hole, wherein the copper foil substrate comprises a surface of the substrate, the surface of the substrate comprising:
a solder mask area, which has a main solder mask layer; and
at least one chip attachment area, which allows at least one chip to be mounted; the at least one chip attachment area has an isolation solder mask layer used to divide the at least one chip attachment area into a plurality of chip sub-attachment areas; each of the chip sub-attachment areas has a sub-attachment area solder paste layer used to connect to the at least one chip, wherein the at least one hole is located in the isolation solder mask layer.

2. The printed circuit board as claimed in claim 1, wherein the surface of the substrate comprises a plurality of pin areas, and each pin area has a pin area solder paste layer.

3. The printed circuit board as claimed in claim 1, wherein the shape of the top view of the isolation solder mask layer is substantially a cross.

4. The printed circuit board as claimed in claim 1, wherein the top view shape of the isolation solder mask layer is substantially a form of intersecting parallel lines.

5. The printed circuit board as claimed in claim 2, wherein the number of the at least one holes is plural, and the distances between the holes are substantially equal.

6. A method for manufacturing a printed circuit board, comprising the following steps:
setting at least one hole in a copper foil substrate;
adding a main solder mask layer and an isolation solder mask layer on a surface of the substrate of the copper foil substrate to form a plurality of chip sub-attachment areas, and making the at least one hole located in the isolation solder mask layer; and
coating a sub-attachment area solder paste layer in each chip sub-attachment area.

7. The method for manufacturing a printed circuit board as claimed in claim 6, wherein after the steps of adding the main solder mask layer and the isolation solder mask layer are completed, a plurality of pin areas are formed on the surface of the substrate, and when the sub-attachment area solder paste layer is coated, the method for manufacturing a printed circuit board further comprises the following steps:
coating a pin area solder paste layer in each pin area.

8. The method for manufacturing a printed circuit board as claimed in claim 6, wherein the shape of the top view of the isolation solder mask layer is substantially a cross.

9. The method for manufacturing a printed circuit board as claimed in claim 6, wherein the top view shape of the isolation solder mask layer is substantially a form of intersecting parallel lines.

10. The method for manufacturing a printed circuit board as claimed in claim 9, wherein the number of the at least one holes is plural, and the distances between the holes are substantially equal.
